(19) United States
(12) Patent Application Publication
(10) Pub. No.: US 2025/0054757 A1
(43) Pub. Date: Feb. 13, 2025

(54) DEFORMATION CONTROL OF MANUFACTURING DEVICES USING FRONT-SIDE IRRADIATION

(71) Applicant: Applied Materials, Inc., Santa Clara, CA (US)

(72) Inventors: Pradeep Kumar Subrahmanyan, San Jose, CA (US); Wonjae Lee, Fremont, CA (US); Ramkumar Karur Shanmugam, Cupertino, CA (US); Olga Kucher, Santa Clara, CA (US); Adaeze Osonkie, Santa Clara, CA (US); San-Kuei Lin, Los Gatos, CA (US)

(21) Appl. No.: 18/796,674

(22) Filed: Aug. 7, 2024

Related U.S. Application Data
(60) Provisional application No. 63/518,707, filed on Aug. 10, 2023.
(60) Provisional application No. 63/601,632, filed on Nov. 21, 2023.

(51) Int. Cl. H01L 21/027; H01L 21/02; H01L 21/66

(52) U.S. Cl. CPC H01L 21/0274; H01L 21/02016; H01L 22/26

(57) ABSTRACT

Disclosed systems and techniques are directed to improvement of semiconductor manufacturing. In one disclosed embodiment, the disclosed systems and techniques include depositing one or more films on a front surface of a substrate, forming a stress compensation layer (SCL) on the one or more deposited films, the SCL causing stress in the substrate to be changed, subjecting the SCL to a stress-mitigation beam to reduce deformation of the substrate, and adding one or more features to at least one of the one or more deposited films.

### RELATED APPLICATIONS

The application claims the benefit of U.S. Provisional Patent Application No. 63/518,707, filed Aug. 10, 2023, entitled “In-Plane Distortion Control Using Ion Implantation into Front Side Deposition layers” and U.S. Provisional Patent Application No. 63/601,632, filed Nov. 21, 2023, entitled “Deformation Control Of Manufacturing Devices Using Front-Side Irradiation,” the contents of both applications being incorporated by reference in their entirety herein.

### TECHNICAL FIELD

The disclosure pertains to semiconductor manufacturing, including processing of wafers and devices manufactured thereon.

### BACKGROUND

Modern semiconducting devices, such as processing units, memory devices, light detectors, solar cells, light-emitting semiconductor devices, devices that deploy complementary metal-oxide-semiconductor (CMOS) structures, and the like, are often manufactured on silicon wafers (or other suitable substrates). Wafers may undergo numerous processing operations, such as physical vapor deposition, chemical vapor deposition, etching, photo-masking, polishing, and/or various other operations. In a continuous effort to reduce the cost of semiconductor devices, multi-layer stacks of dies, insulating films, patterned and/or doped semiconducting films, and/or other features are often deposited on a single wafer, resulting in high aspect ratio devices, which are used, e.g., in 3D flash memory devices and other applications. Deposition, patterning, etching, polishing, etc., of stacks of multi-layered structures often result in significant stresses applied to the underlying wafers. Such stresses lead to both an out-of-plane distortion and an in-plane distortion of features supported by the wafers. These distortions result in misalignment of deposited features and can significantly degrade quality of manufactured devices.

### SUMMARY

In one embodiment, disclosed is a method of manufacturing a semiconductor device, including depositing one or more films on a front surface of a substrate and forming a stress-compensation layer (SCL) on the one or more deposited films, the SCL causing stress in the substrate to be changed. The method further includes subjecting the SCL to a stress-mitigation beam to reduce deformation of the substrate and adding one or more features to at least one of the one or more deposited films.

In another embodiment, disclosed is a system that includes a memory and a processing device communicatively coupled to the memory. The processing device is to cause performance of operations that include depositing one or more films on a front surface of a substrate and forming an SCL on the one or more deposited films, the SCL causing stress in the substrate to be changed. The operations further include subjecting the SCL to a stress-mitigation beam to reduce deformation of the substrate and adding one or more features to at least one of the one or more deposited film.

In another embodiment, disclosed is a semiconductor manufacturing system that includes one or more processing chambers to deposit one or more films on a front surface of a substrate and form an SCL on the one or more deposited films, the SCL causing stress in the substrate to be changed. The one or more processing chambers are further to subject the SCL to a stress-mitigation beam to reduce deformation of the substrate and add one or more features to at least one of the one or more deposited films.

### BRIEF DESCRIPTION OF THE DRAWINGS

The present disclosure will be understood more fully from the detailed description given below and from the accompanying drawings of various embodiments of the disclosure.

FIGS. 1A-1B illustrate schematically a process of manufacturing high aspect ratio structures, the process including irradiation of masks with a stress-mitigation beam, according to at least one embodiment.

FIGS. 2A-2F show a substrate-wide view of the process of FIGS. 1A-1B of semiconductor manufacturing that includes irradiation of masks with a stress-mitigation beam, according to at least one embodiment.

FIGS. 3A-E illustrate schematically a process of correcting substrate deformation using a stress-mitigation beam applied to the front side of a wafer, according to at least one embodiment.

FIG. 4 illustrates an example Zernike polynomial decomposition of one actual deformation (top left) of a substrate, in arbitrary units, into a paraboloid bow deformation (top right), a saddle deformation (bottom left), and a residual deformation, (bottom right), according to at least one embodiment.

FIG. 5 is a flowchart illustrating an example method of mitigation of substrate stress and deformation using front-side irradiation, in accordance with at least one embodiment.

FIG. 6 is a flowchart illustrating an example method of determining front-side irradiation parameters, in accordance with at least one embodiment.

FIGS. 7A-7H illustrates schematically an example process of manufacturing a logic device using a stress-mitigation beam to irradiate a front side-deposited layer, according to at least one embodiment nt.

FIG. 8A-8B illustrates schematically an irradiation system capable of performing irradiation of stress compensation layers, according to at least one embodiment.

FIG. 9 depicts a block diagram of an example computer system capable of supporting operations of the present disclosure, according to at least one embodiment.

### DETAILED DESCRIPTION

Modern technology often aims to maximize chip area utilization by manufacturing three-dimensional devices with vertical stacks of multiple layers of semiconducting structures. For example, in NAND flash memory devices, lateral relative arrangement (CMOS near Array, or CnA) of memory cells (e.g., floating gate transistors) and peripheral transistors (e.g., CMOS circuitry used to support write/read operations with memory cells) has mostly given way to a vertical arrangement (CMOS under Array, or CuA) in which peripheral CMOS circuitry is disposed below an array of memory cells. In some instances, stacks of layers of memory cells can be manufactured on top of other stacks creating a structure in which precise alignment of various features within the layers is important for proper functioning of the manufactured devices. In one example, a stack of multiple (e.g., a hundred or more) alternating oxide (O) and nitride (N) layers (e.g., silicon oxide and silicon nitride layers, in one example) can be deposited on top of a silicon wafer and then covered with a mask layer (e.g., a carbon hard mask). Although O and N layers are referenced throughout the instant disclosure, many other layers/films can be deposited on wafers, including but not limited to polycrystalline silicon layers. For example, a three-dimensional (3D) Dynamic Random-Access Memory (DRAM) manufacturing, a stack of alternating Si₁₋ₓGeₓ (SiGe) alloy layers and silicon (e.g., epitaxial silicon) layers can be deposited on top of a silicon substrate to form. A photoresist layer can be deposited on the mask layer with a defined pattern of holes (channel holes), slits, and/or various other openings that are to be transferred to the stack of ON layers or SiGe layers via the mask. A photolithography can then be performed to open the mask according to the defined pattern (with the photoresist material protecting unexposed areas of the mask) and allow access to the stack of ON layers or SiGe layers. An etching process can be carried out to etch the regions of the ON layers or SiGe layers located under the opened portions of the mask to form deep vertical channels and/or slits that can extend all the way through the stack and down to the wafer. The channels/slits can then be used to deliver target materials across various ON layers or SiGe layers, e.g., to replace N layers or silicon-germanium layers with conducting materials (such as Tungsten, Molybdenum, and/or the like) and to form multi-layered transistor arrays within the vertical channels, and/or the like.

The arrays of transistors and/or other features deposited into the stack of layers may need to be precisely aligned with the matching structures deposited on the top surface of the wafer (e.g., source lines of conducting circuits that support electronic operations of the transistor arrays). Furthermore, one or more additional stacks of layers can be deposited on top of the previously deposited stacks, e.g., to increase the vertical count of memory cells/transistors and, respectively, increase the density of cells per area of the NAND or 3D DRAM device. Processing such additional stacks can be performed as described above, e.g., by placing another mask above an additional stack, opening the mask, and etching vertical channels/slits through the additional stack(s). The channels etched through the top stack(s) have to align with the corresponding channels etched in the bottom stack(s), to ensure that good electrical contacts are formed between corresponding arrays of memory cells.

Alignment of channels, slits, and/or various other features across a vertical stack of multiple layers/films, however, can be hindered by deformation of the substrate, e.g., in-plane and/or out-of-plane deformation. Such deformations can be caused by stresses arising at contacts between the substrate and the stacks of layers, between layers of individual stacks, by stresses arising from patterning of features within the layers, and/or the like. This can result in inoperable and/or sub-optimal devices and a corresponding decrease in the yield of the manufacturing process.

Existing technology includes a number of methods that address substrate deformation. For example, a deformed (warped) substrate with various films and features deposited on one side (also referred to as the front side, top side, or main side) can be coated on the back side (also referred to as the bottom side) with a film that exerts compression stress or tensile stress on the substrate. Such a back side-deposited deformation-correcting film, also referred to as a stress-compensation layer herein, can impart a uniform (or global) stress to the entire substrate and reduce an amount of deformation of the substrate. Additional stress-mitigation can be achieved by implanting ions into the stress-compensation layer, e.g., using a beam of ions to bombard the stress-compensation layer, to adjust the stress in the stress-compensation layer and, consequently, to further correct the deformation of the underlying substrate. Ion implantation can be performed globally or locally (e.g., to certain selected areas of the substrate). Using backside stress mitigation techniques involves using extraneous materials and films that do not contribute to the device functionally but add extra complexity and introduce additional risk of sample non-uniformity.

Aspects and embodiments of the present disclosure address these and other challenges of the modern semiconductor manufacturing technology by providing for systems and techniques that mitigate substrate stresses and deformations and improve alignment of features in high aspect ratio devices without introducing additional materials and complexity. In some embodiments, the hard mask deposited on top of a stack of layers/films can be used as a stress-compensation layer. More specifically, prior to covering the hard mask with the photoresist and/or other lithography-related materials, the hard mask can be exposed to irradiation by a stress-mitigation beam. The stress-mitigation beam can include particles (e.g., ions, electrons), electromagnetic waves (e.g., UV light, far UV light, extreme UV light, visible light, infrared light, etc.), and/or a suitable combination thereof. The stress-mitigation beam strikes the hard mask and changes the bonding network of the hard mask. For example, the stress-mitigation beam of low energy may interact with surface atoms of the hard mask, e.g., removing some of the surface atoms, effectively implementing etching of surface regions of the hard mask. The effectiveness of such etching may be controlled by a choice of ion species/radicals/ambient gasses. In another example, the stress-mitigation beam of high energy can deposit ions inside the hard mask. Ions and/or photons of the beam can break of the bonding network (or crystal lattice) of the hard mask forming vacancies therein, and can further cause annealing due to local heating, UV curing, and/or other effects. Substitution defects and/or vacancies created by the particles of the stress-mitigation beam modify (e.g., reduce) stress in the hard mask and, through the mask, in the wafer or other substrate. The intensity and/or dose (the intensity integrated over time) of the stress-mitigation beam can vary with a location within the hard mask and can be determined (e.g., simulated, modeled, etc.) in a way that maximally relieves the stress in the hard mask and, further, in the substrate. This causes the combination of the substrate, the deposited layers/films, and the hard mask to flatten and facilitates precise alignment of features that are patterned on the substrate, etched in one or more stacks of layers, and/or the like, and improves quality of the manufactured devices. The intensity/doses of irradiation can be determined based on measured deformation of the substrate (with layers/films/mask deposited thereon), e.g., using various optical measurement techniques. Multiple techniques can be used to determine optimal intensity and/or dose of the stress-mitigation beam, such as Monte Carlo simulations, influence function computations, and/or other techniques, as disclosed below.

Advantages of the disclosed embodiments include but are not limited to a significant reduction of the costs of stress correction of the substrate shapes in semiconductor manufacturing and a more accurate alignment of features manufactured on substrates, including high aspect ratio features in vertically grown semiconductor devices.

A “wafer” or “substrate,” as used herein, refers to any substrate or material surface formed on a substrate upon which film processing is performed during a fabrication process. For example, a wafer surface on which processing can be performed includes any intrinsic (undoped) or doped materials such as silicon, silicon oxide, silicon nitride, strained silicon, silicon on insulator, silicon oxides with carbon, amorphous silicon, germanium, gallium arsenide, glass, sapphire, plastic, and any other materials such as metals, metal nitrides, metal alloys, and other conductive materials, depending on the application. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

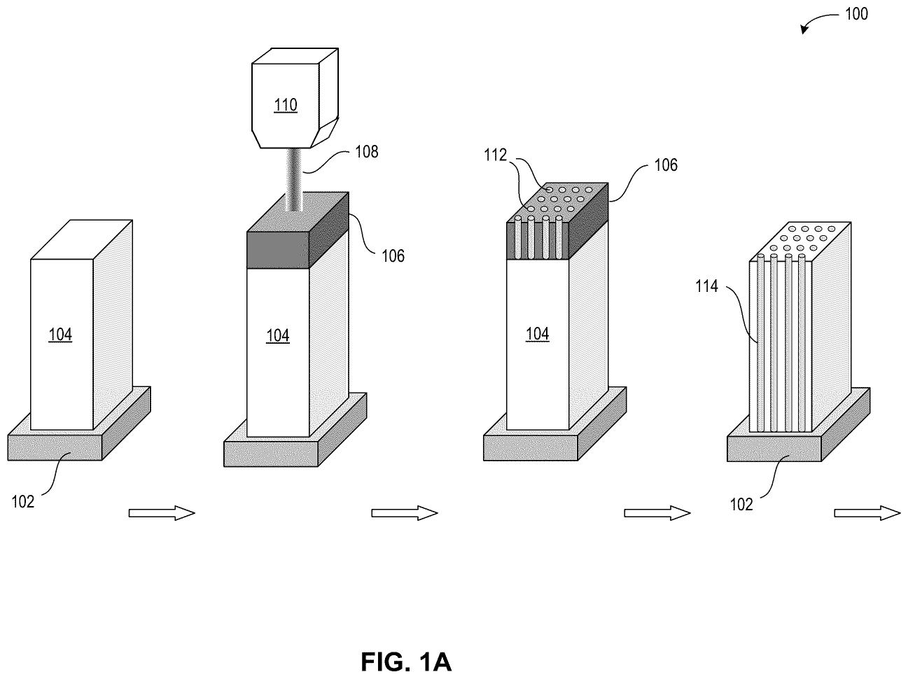

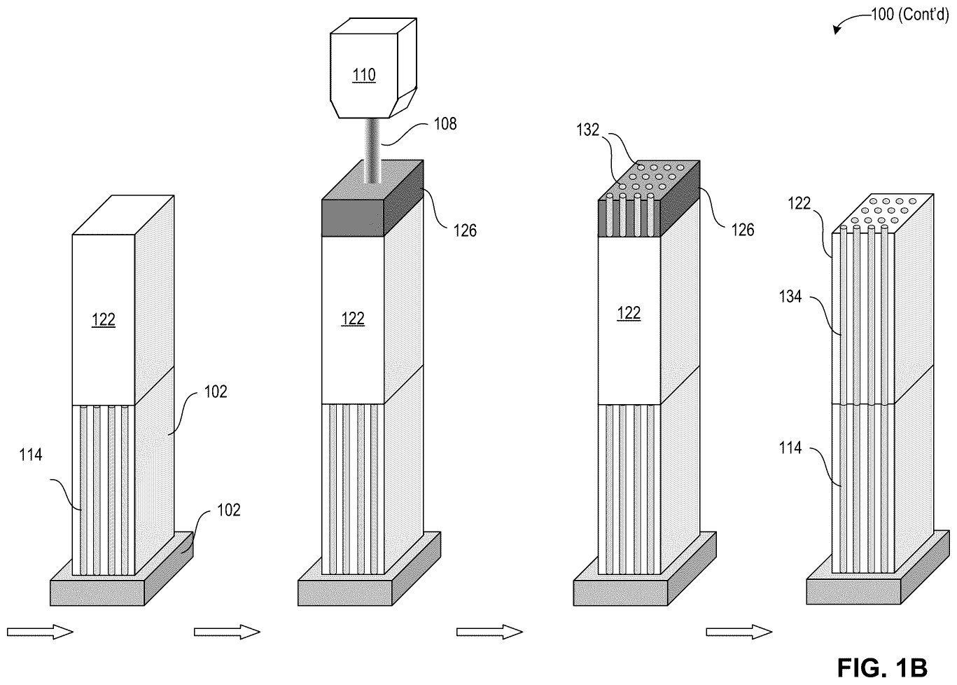

FIGS. 1A-1B illustrate schematically a process 100 of manufacturing high aspect ratio structures, the process including irradiation of masks with a stress-mitigation beam, according to at least one embodiment. Evolution (marked with arrows) of an individual structure is illustrated in FIG. 1A. More specifically, a first stack 104 of layers/films can be grown (or deposited) on a substrate 102, a portion of which is shown in FIG. 1A. Stack 104 can be a stack of alternating O and N layers or any other suitable stack, which can include any number (e.g., three or more) of periodically repeated layers. It should be understood that FIGS. 1A-1B may not be to scale and that the thickness of the wafer can significantly exceed the height of first stack 104. For example, a height of the wafer can be of the order of 0.5-1 mm, the thickness of an individual O or N layer can be of the order of 100 nm, and the height of first stack 104 can be of the order of 10 μm. In some embodiments, the thickness of O and/or N layer can be 20-30 nm, or even below 20 nm. A mask (e.g., hard mask) 106 can then be deposited on top of the first stack 104. In some embodiments, one or more additional stress-compensation layers can be deposited together with mask 106. In some embodiments, after deposition, mask 106 can undergo annealing, e.g., to reduce globally the stress of mask 106 and/or pre-condition mask 106 prior to stress mitigation by exposing mask 106 to a beam of light.

In some embodiments, a stress-mitigation beam 108 can then be applied to mask 106 (or to one or more additional stress-compensation layers) to deliver a position-dependent dose of particles and/or photons n(x,y), where x, y are in-plane coordinates within the plane of the wafer/mask. Stress-mitigation beam 108 can be generated by a suitable collimating and focusing column 110. Application of stress-mitigation beam 108 causes stress in the structure that contains substrate 102, first stack 104, and mask 106 to decrease, resulting in the flattening of the structure (reduced deformation).

Following stress-mitigation, one or more additional layers can be deposited on mask 106, including but not limited to dielectric anti-reflective coating (DARC) layer, ashable hard mask (AHM, often made of amorphous carbon), and a bottom anti-reflective coating (BARC) layer. Mask 106 can be opened, e.g., using any suitable lithography techniques, to create channels 112 extending over the height of mask 106 or any other target pattern. More specifically, a photoresist layer (now shown in FIG. 1A, for simplicity) can be deposited on mask 106 and DARC/AHM/BARC layers. A photolithography can then be used to create a target pattern, e.g., a pattern of channel holes to be transferred to mask 106 and first stack 104. An etch process, e.g., Mask Open Etch, can be used to transfer the target pattern to mask 106 facilitated by PR/BARC/AHM/DARC layers. The Mask Open etch creates pattern of channels 112 (as well as any other features, including but not limited to slits, and/or other openings) in mask 106. An additional etch process-channel hole etch, memory hole etch, dielectric etch—can be used to transfer channels 112 (or other features) to first stack 104 forming extended channels 114 that can run all the way down to substrate 102, in some embodiments. Etching can consume at least some of mask 106; unconsumed parts of mask 106 can be removed, e.g., dissolved or evaporated. Although, for simplicity, FIG. 1A illustrates formation of cylindrical channels 114, slits or any other vertical features can be also etched in a similar manner.

As illustrated in FIG. 1B, the described process can be repeated for one or more additional stacks of layers/films, which can be placed on top of first stack 104. More specifically, a second stack 122 can be deposited on top of first stack 104 and a mask 126 can be deposited on top of second stack 122. Stress-mitigation beam 108 can be used to irradiate mask 126. Subsequently, DARC, BARC, and a photoresist can be placed on mask 126 and photolithography can be used to create channels 132 in mask 126. Channels 132 can then be used to perform etching of second stack 122 and form channels 134 that extend down the length of second stack 122. Because of application stress-mitigation beam 108 to masks 106 and 126, channels 134 in second stack 122 can be accurately aligned with channels 114 in first stack 104, essentially forming continuous pathways for material deposition throughout the height of the two (or more) stacks. These pathways can be used, e.g., to replace nitrogen in the N layers with metals (e.g., Tungsten) and to form multi-layered transistor arrays within channels 114 and 134. Although the example of FIGS. 1A-1B illustrates stress mitigation and alignment of two stacks of layers/films, three or more stacks can be assembled in a similar manner.

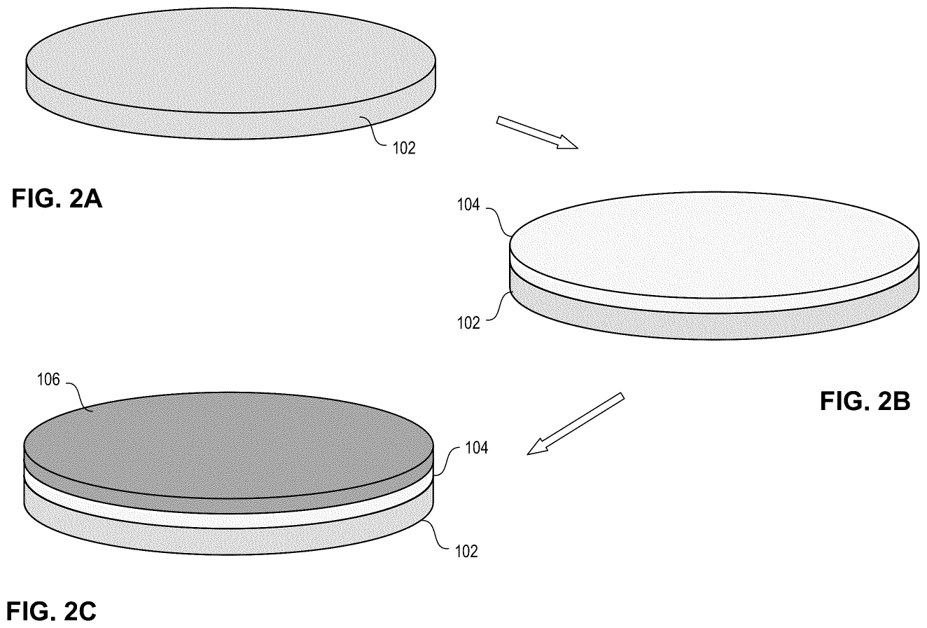

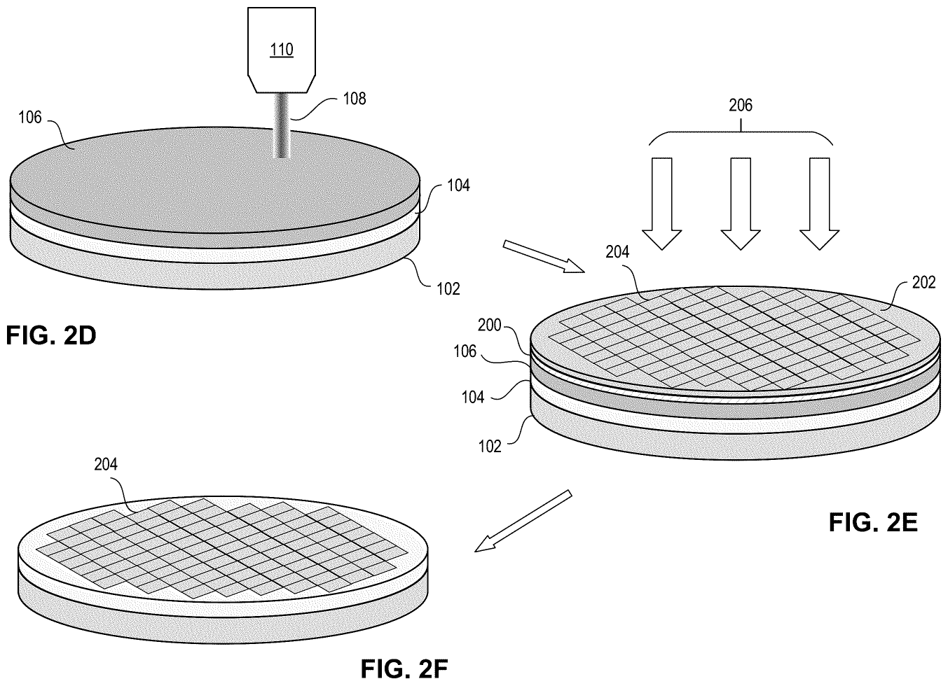

FIGS. 2A-2F show a substrate-wide view of the process 100 of FIGS. 1A-1B of semiconductor manufacturing that includes irradiation of masks with a stress-mitigation beam, according to at least one embodiment. FIG. 2A shows a substrate 102, which can be a bare wafer or a wafer with one or more features patterned thereon. In some embodiments, substrate 102 can further undergo some additional treatment, such as annealing, e.g., after deposition of mask 106 and before application of stress-mitigation beam 108. FIG. 2B illustrates the first stack 104 deposited on substrate 102. At this stage in the process 100, first stack 104 can be a stack of uniform (unpatterned) films. FIG. 2C illustrates mask 106 deposited on top of first stack 104. FIG. 2D illustrates application of stress-mitigation beam 108 produced by collimating and focusing column 110 and directed to mask 106. FIG. 2E schematically illustrates photolithography of mask 106. More specifically, mask 106 can be covered with one or more DARC and/or BARC layers 200 topped with photoresist 202. A target pattern 204 can be created in photoresist 202. Target pattern 204 can include chip boundaries, area boundaries, slits, channels, and/or any other applicable features. Photolithography can be performed using any suitable radiation 206 (e.g., UV light, visible light, infrared light, and/or the like). Photolithography transfers patterns 204 to mask 106. Mask 106 is then used during etching of first stack 104 to form patterns 204 in first stack 104. FIG. 2F illustrates first stack 104 with etched patterns 204 (with mask 106 consumed by the etching or removed during post-etching processing). Additional stacks of layers can further be added by repeating operations illustrated in FIGS. 2B-2E.

Prior to irradiating the masks with stress-mitigation beams, the amount of stress in the wafer (with films and mask deposited thereon) can be determined by measuring a profile h(\vec{r}) of the wafer. The profile h(\vec{r}) can refer to the vertical coordinate of the top surface of the mask. In some instances, stress in the wafer can be uniform and isotropic, σₓₓ≈σ_{yy}. In some instances, stress in the wafer can be anisotropic, σₓₓ≠σ_{yy}. Certain feature patterns can result in stresses that are compressive along one direction, e.g., σₓₓ>0, and tensile along a perpendicular direction, σ_{yy}<0, resulting in saddle-shaped wafers. Such saddle-shaped features can arise, for example, in stacks of materials with directional patterning, e.g., patterning of wordlines in NAND devices.

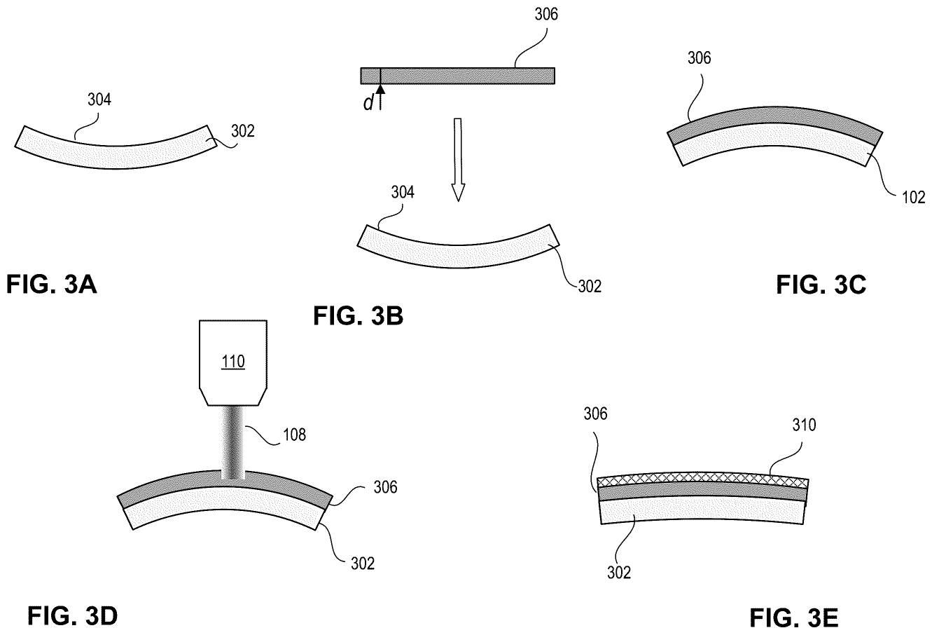

In some embodiments, a vertical profile of wafer deformation z=h(\vec{r}) can be measured using optical metrology (e.g., optical interferometry) techniques. In some embodiments, wafer deformation z=h(\vec{r}) can be measured after a stack of layers/films is deposited on the wafer. The wafer profile h(\vec{r}) can then be represented via a number of parameters that qualitatively and quantitatively characterize geometry of the wafer deformation, e.g., a set of Zernike (or a similar set of) polynomials, h(\vec{r})=ΣⱼAⱼZⱼ(\vec{r}). Consecutive coefficients A₁, A₂, A₃, A₄ . . . represent weights of specific geometric features (elemental deformations) of the wafer described by the corresponding Zernike polynomials Zⱼ(\vec{r}). In some embodiments, a material of hard mask can be selected based on the sign of a paraboloid bow coefficient A₄. In some embodiments, selection of a thickness d of a hard mask can be made based on a value of the paraboloid bow coefficient A₄. The hard mask can then also serve as a stress-mitigation layer. The hard mask can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). As illustrated in FIGS. 3A-3E below, thickness d of the stress-compensation layer can be selected to overcorrect the wafer deformation to some degree. The overcorrection can be chosen in conjunction with a type of stress-mitigation beam (e.g., ion implants, photons, electrons, etc.), a type of implant species, energy, and dose to ensure maximum effect from the stress mitigation. Stress in the combined structure of the wafer, films, and the hard mask can then be modified by the stress-mitigation beam that strikes the hard mask and changes its crystal structure. Substitution defects and/or vacancies created by the beam mitigate (e.g., reduce) stress in the stress-compensation layer and can reduce the degree of stress overcorrection caused by the hard mask deposition. This causes the wafer to flatten.

FIGS. 3A-E illustrate schematically a process of correcting substrate deformation using a stress-mitigation beam applied to the front side of a wafer, according to at least one embodiment. FIG. 3A depicts a substrate 302 having a deformation, which can include a paraboloid bow deformation (with positive coefficient A₄>0, as illustrated) and can further include other deformations, including saddle deformation, residual deformation, etc. The wafer's front side 304 can include any number of features, e.g., deposition and/or etching patterns, a stack of layers/films, and/or any other structures. FIG. 3B illustrates deposition of a hard mask 306 on the front side 304 of substrate 302. Hard mask 306 can be (or include) a carbon-based mask (e.g., amorphous carbon), a chromium-based mask, or any other type of mask. In some embodiments, hard mask 306 can include layers of multiple materials. In some embodiments, a material of hard mask 306 can be selected in view of the sign of coefficient A₄. For example, for a positive bow, A₄>0, hard mask 306 can be selected to have a tensile stress (as illustrated in FIGS. 3B-3E). Conversely, for a negative bow, A₄<0, hard mask 306 can be selected to have a compressive stress (not shown in FIGS. 3B-3E). Hard mask 306 can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). In some embodiments, a thickness d of hard mask 306 can be selected to overcorrect the wafer deformation to some degree, e.g., as illustrated in FIG. 3C where a positive paraboloid is overcorrected to a negative paraboloid bow. The thickness-dependent paraboloid bow correction A_{corr}(d) changes wafer deformation from h(r, ϕ) to h_{corr}(r, ϕ):

$${h}_{corr} ( r , ϕ ) = h ( r , ϕ ) + {A}_{corr} ( d ) \cdot {Z}_{4} ( r , ϕ ) .$$

The degree of overcorrection can be chosen in conjunction with a type and parameters (e.g., energy, dose, etc.) of a specific stress-mitigation beam to be used on hard mask 306. The overcorrection can make the combined structure of substrate 302 and hard mask 306 susceptible to further control of stress (and thus control of deformation of the wafer h_{corr}(r, ϕ)). As illustrated in FIG. 3D, collimating and focusing column 110 can generate a stress-mitigation beam 108 that strikes hard mask 306 and changes its elastic properties, e.g., by creating vacancies, breaking crystal bonds, depositing ions, and/or via any other applicable mechanisms. Stress-mitigation beam 108 can carry photons, electrons, silicon ions, phosphorus ions, argon ions, neon ions, xenon ions, krypton ions, and/or the like. In some embodiments, the energy and type of ions in stress-mitigation beam 108 can be selected to limit the implanted ions to the volume of hard mask 306 without allowing the ions to reach substrate 302 (and/or any layers/films deposited on substrate 302). Ions that lodge in hard mask 306 create substitution defects therein. Additionally, the ions leave a trail of vacancy defects along paths of propagation in hard mask 306. The substitution defects and/or vacancies mitigate (e.g., reduce) stress in hard mask 306 and can reduce the degree of stress overcorrection caused by the hard mask deposition. This causes the combination of substrate 302 and hard mask 306 to flatten.

In some embodiments, the number of ions ΔNᵢ deposited per small area ΔA=ΔxΔy (or the total amount of photon energy applied to this area) of substrate 302 can be determined using simulations (performed as described in more detail below) based on the local value of the corrected deformation h_{corr}(r, ϕ), which may include a saddle deformation, a residual deformation, and the part of the paraboloid bow deformation A_{corr} (d)+A₄ that has been overcorrected by the deposition of stress-compensation layer 108. The target local density n(x,y)=ΔNᵢ/ΔxΔy of the ions can be delivered by controlling the scanning velocity ν of stress-mitigation beam 108. In some embodiments, stress-mitigation beam 108 has a profile that can be approximated with a Gaussian function, e.g., the ion flux j(ρ)=j₀exp(−x²/a²−y²/b²), where x and y are Cartesian coordinates, j₀ is the maximum ion flux at the center of the beam, and a and b is are characteristic spreads of the beam along the x-axis and y-axis, respectively. Correspondingly, a point that is located at distance y from the path of the center of the beam receives an ion dose that includes the following number of ions:

$$\frac{Δ {N}_{i}}{Δ x Δ y} = \frac{{j}_{0}}{v} {{\int }^{∞}}_{- ∞} {dxe}^{- {x}^{2} / {a}^{2} - {y}^{2} / {b}^{2}} = \frac{{j}_{0} \sqrt{π}}{va} {e}^{- {y}^{2} / {b}^{2}} .$$

Correspondingly, by reducing the scanning velocity ν, the number of ions received by various regions of hard mask 306 can be increased, and vice versa. Additionally, stress-mitigation beam 108 can perform multiple scans with different offsets y so that various points of hard mask 306 receive multiple doses of ions with different factors e^{-y}^{²}^{/b}^{²} that can average to a target dose. For example, after n passes of stress-mitigation beam 108, each made with a respective velocity νₖ at a different distance yₖ from the center of the beam to the area ΔxΔy, the total dose of ions (or amount of electromagnetic radiation) received by this area will be

$$n ( x , y ) = \frac{Δ {N}_{i}}{Δ x Δ y} {\vert}_{total} = {j}_{0} \sqrt{π} {\sum }_{k = 1}^{n} \frac{{e}^{- {y}_{k}^{2} / {b}^{2}}}{{av}_{k}} .$$

As illustrated in FIG. 3E, a stress-mitigation layer 310 forms as part of hard mask 306 and results in a significant mitigation of deformation of substrate 302, including saddle and residual deformations. In some embodiments, an additional stress-compensation layer can be deposited on the back side of substrate 302 (not shown in FIGS. 3A-3E), e.g., for additional parabolic deformation mitigation.

In some embodiments, the intensity and/or total amount of irradiation per various areas of the wafer can be determined using simulations, e.g., Monte Carlo simulations. The Monte Carlo simulations can be performed for a film made of the actual material used in mask deposition and having a specific thickness d. An initial Monte Carlo simulation can be performed for specific baseline (default) conditions of the particle irradiation (e.g., default settings of an ion implantation apparatus). The baseline conditions can include a default type of particles, a default energy of the particles, a default dose of particles to be applied to the mask or other stress-compensation layer (e.g., a default velocity of scanning and a default scanning pattern), and the like. The baseline conditions can subsequently be modified (e.g., optimized) using the Monte Carlo simulations. The Monte Carlo simulations can use calibration data collected (measured) for actual particle irradiation performed for various ion/photon/electron energies, types of ions, types and materials of masks/layers, angles of particle incidence on the films, and/or the like.

In some embodiments, the implantation map n(\vec{r}) can be computed using an influence function G (\vec{r}; \vec{r}′) that characterizes a response (e.g., deformation) at a point \vec{r} of the wafer as caused by a point-like force applied at another point \vec{r}′ of the wafer. In some embodiments, the influence function G(\vec{r}; \vec{r}′), also known as the Green's function, can be determined from computational simulations or from analytical calculations. In some embodiments, the influence function can be determined from one or more experiments, which can include performing ion implantation into a film deposited on a reference wafer.

In some embodiments, wafer deformation h(\vec{r})=h_{quad}(\vec{r})+hᵣₑₛ(\vec{r}) can be represented (decomposed) as a combination of a quadratic h_{quad}(\vec{r}) and residual (non-quadratic) hᵣₑₛ(\vec{r}) contributions. The quadratic deformation can include a parabolic (paraboloid) part hₚₐᵣ(\vec{r}), which has the complete axial symmetry, and a saddle part h_{saddle}(\vec{r}). The thickness d of hard mask 306 can be computed (or empirically determined) in such a way that the mask is to apply a desired target stress to the wafer. To eliminate a non-uniform saddle deformation, hard mask 306 can be of such thickness/material that turns the saddle deformation into a cylindrical deformation having a definite sign throughout the area of the wafer. The uniform-sign cylindrical deformation (as well as a residual higher-order non-quadratic deformation) can then be mitigated with irradiation by a stress-mitigation beam. In some embodiments, a cylindrical decomposition is not unique and can be either positive (upward-facing cylindrical deformation) or negative (downward-facing cylindrical deformation). Both decompositions can be analyzed and a decomposition that enables a more effective stress mitigation can be selected. For example, a decomposition that is characterized by a smaller parabolic bow deformation can be selected. The parabolic bow deformation can be mitigated using a choice of mask 306 (e.g., type and thickness) while the remaining cylindrical deformation (and the higher-order residual deformation) can be addressed by appropriately selected ion or photon irradiation doses n(\vec{r}).

In some embodiments, mitigation of a cylindrical deformation or a saddle deformation can include identifying principal axes (directions) of the cylinder/saddle and a magnitude of the cylindric/saddle deformation and directing the stress-mitigation beam into appropriately selected edge regions of the hard mask. For example, individual edge regions to which the beam is directed can have a width that is at or below 30% of a diameter of the wafer. Residual higher-order (ripple) deformations can then be mitigated with further irradiation into the area of the mask.

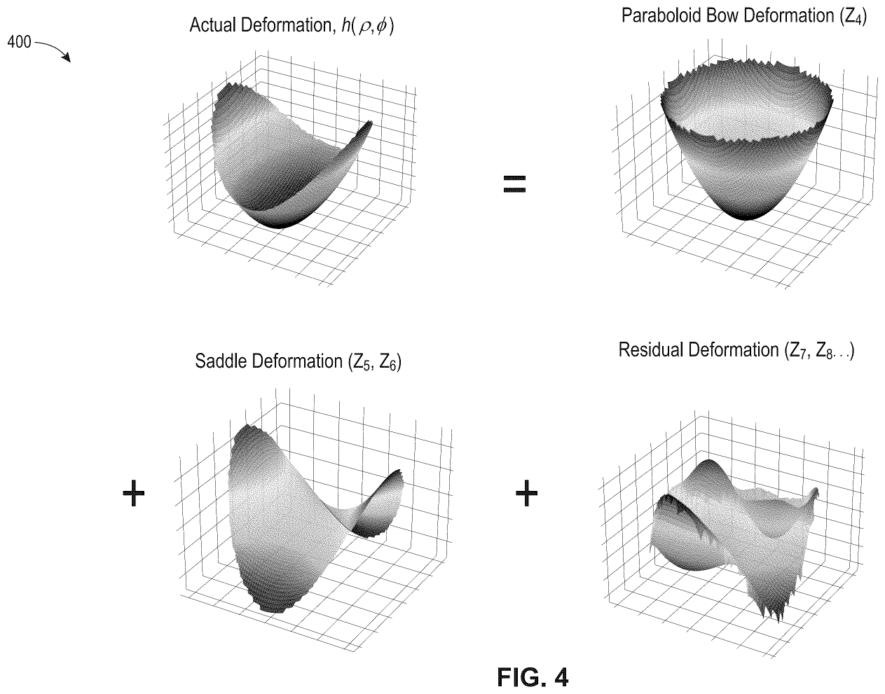

Some of these techniques will now be described in more detail. In one embodiment, a vertical profile of wafer deformation z=h(\vec{r}) can be measured using optical metrology techniques. For example, an interferogram of the profile h(\vec{r}) can be obtained using optical interferometry measurements. The wafer profile h(\vec{r}) can then be represented via a number of parameters that qualitatively and quantitatively characterize geometry of the wafer deformation. In some embodiments, a set of Zernike (or a similar set of) polynomials may be used to represent the wafer profile,

$$h ( \vec{r} ) = {\sum }_{j} {A}_{j} {Z}_{j} ( \vec{r} ) ,$$

where the planar radius-vector \vec{r}=(r, ϕ) may be represented as the radial coordinate r and the polar angle ϕ within the (average) plane of the wafer. Consecutive coefficients A₁, A₂, A₃, A₄ . . . represent weights of specific geometric features (elemental deformations) of the wafer described by the corresponding Zernike polynomials Z₁(r, ϕ), Z₂(r, ϕ), Z₃(r, ϕ), Z₄(r, ϕ) . . . . (Herein, the Noll indexing scheme for the Zernike polynomials is being referenced.) The first three coefficients are of less interest as they describe a uniform shift of the wafer (coefficient A₁, associated with the Z₁(r, ϕ)=1 polynomial), a deformation-free x-tilt that amounts to a rotation around the y-axis (coefficient A₂, associated with the Z₂(r, ϕ)=2r cos ϕ polynomial), and a deformation-free x-tilt that amounts to a rotation around the x-axis (coefficient A₃, associated with the Z₃(r, ϕ)=2r sin ϕ polynomial) that can be eliminated by a realignment of the coordinate axes. The fourth coefficient A₄ is associated with Z₄(r, ϕ)=\sqrt{3}(2r²−1) and characterizes an isotropic paraboloid deformation (“bow”). The fifth A₅ and the sixth A₆ coefficients are associated with Z₅ (r, ϕ)=\sqrt{6}r² sin 2ϕ and Z₆ (r, ϕ)=\sqrt{6}r² cos 2ϕ polynomials, respectively, and characterize a saddle-type deformation. The A₅ coefficient characterizes a saddle shape that curves up (A₅>0) or down (A₅<0) along the diagonal y=x and curves down (A₅>0) or up (A₅<0) along the diagonal y=−x. The A₆ coefficient characterizes a saddle shape that curves up (A₆>0) or down (A₆<0) along the x-axis and curves down (A₆>0) or up (A₆<0) along the y-axis. The higher coefficients A₇, A₈, etc., characterize progressively faster variations of the wafer deformation h(r, ϕ) along the radial direction, along the azimuthal direction, or both and collectively represent a residual deformation, hᵣₑₛ(r, ϕ)=h(r, ϕ)−Σⱼ₌₄⁶AⱼZⱼ(r, ϕ). FIG. 4 illustrates an example Zernike polynomial decomposition 400 of one actual deformation h(r, ϕ) (top left) of a substrate, in arbitrary units, into a paraboloid bow deformation A₄Z₄(r, ϕ) (top right), a saddle deformation A₅Z₅(r, ϕ)+A₆Z₆ (r, ϕ) (bottom left), and a residual deformation, hᵣₑₛ (r, ϕ) (bottom right), according to at least one embodiment.

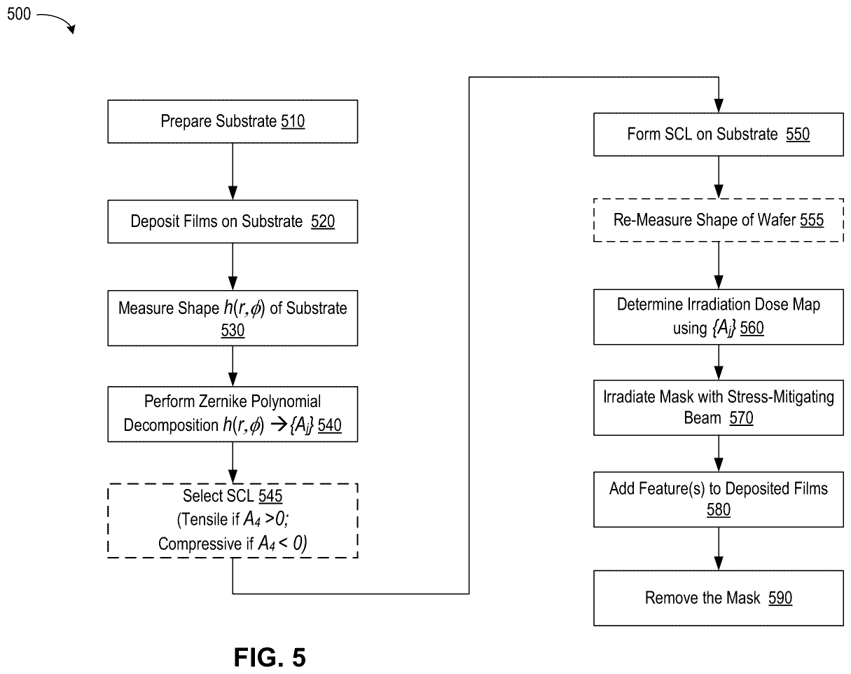

FIG. 5 is a flowchart illustrating an example method 500 of mitigation of substrate stress and deformation using front-side irradiation, in accordance with at least one embodiment. Method 500 can be performed using a semiconductor manufacturing system that includes one or more processing chambers, e.g., deposition chamber(s), plasma chamber(s), etching chamber(s), polishing chamber(s), film removal chamber(s), beam irradiation chamber(s), optical inspection chamber(s), and/or the like. The processing chambers can be connected to one or more transfer chambers, which can be equipped with robot(s) to handle substrates, e.g., moving substrates into and out of processing chambers. The transfer chamber can further be connected to a load-lock chamber (Front-End Interface) that can be coupled to one or more Front Opening Unified Pod carriers that hold bare substrates, processed substrates, partially processed substrates, and/or the like. Operations performed by the semiconductor manufacturing system, including any, some or all operations of method 500, can be performed responsive to instructions issued by a suitable computing device having a processing logic and memory to store the instructions.

At block 510, method 500 can include preparing a substrate, including but not limited to obtaining a bare substrate, preprocessing the bare substrate, e.g., polishing the substrate, removing stains and/or residue from the substrate, and/or the like, and/or performing any number of similar operations. At block 520, method 500 can continue with depositing one or more films/layers on the substrate. The layers can include a layer of conducting features, e.g., source lines to be used as part of memory cell (transistor) circuitry. In some embodiments, the layers can include multiple alternating N(itride) and O(xide) layers to be used as hosts of memory cells and separations between memory cells. In some embodiments, the layers can include alternating silicon and silicon-germanium alloy layers. At block 530, method 500 includes measuring the shape of the substrate, e.g., a displacement of a surface (e.g., the top surface) of a substrate as a function of some in-plane coordinates, e.g., polar coordinates z=h(r, ϕ), Cartesian coordinates, z=h(x,y), or any other suitable coordinates. At block 540, method 500 includes decomposition of the determined shape over a suitable set of polynomials, e.g., Zernike polynomials, and obtaining a set of polynomial expansion coefficients, {Aⱼ}=(A₁, A₂, A₃, A₄, A₅, A₆, A₇, . . . , each coefficient in the set characterizing a degree of presence of a particular elemental geometric shape in the substrate's deformation.

In some embodiments, method 500 can include a decision-making block 545 to select a type of a mask (to serve as SCL) to be used with the substrate. The mask can be selected to serve a dual purpose: to facilitate etching of the stack of layers/films deposited at block 520 and to facilitate mitigation of stress compensation of the substrate. For example, a decision at block 545 can be made based on the coefficient that determines a degree of parabolicity of the deformation, e.g., coefficient A₄. If the substrate is curved downwards (towards the back side of the substrate), a tensile mask can be selected for front side deposition at block 545. If the substrate is curved upward (towards the front side of the substrate), a compressive mask can be selected for front side deposition. Operations of block 545 can also include determining a type of a material for the mask to be deposited and a thickness d of the mask. In some embodiments, this determination can be made based on multiple expansion coefficients (more than just the paraboloid bow coefficient A₄) from the set {A₁} or the full profile h(r, ϕ). In one specific non-limiting example, the thickness d can be determined as follows. First, a target paraboloid deformation Ã₄ can be determined that is sufficient to overcompensate for the measured substrate deformation, e.g., for h(r, ϕ)<0, the following condition can be satisfied:

$${\tilde{A}}_{4} {Z}_{4} ( ρ , ϕ ) + h ( r , ϕ ) ≡ ( {\tilde{A}}_{4} + {A}_{4} ) {Z}_{4} ( ρ , ϕ ) + {A}_{5} {Z}_{5} ( ρ , ϕ ) + {A}_{5} {Z}_{6} ( ρ , ϕ ) + … > 0.$$

In other words, the target paraboloid deformation Ã₄ can be chosen sufficiently large to compensate for the paraboloid deformation (A₄), saddle deformation (A₅ and A₆) and the residual deformation (A₇, and higher coefficients). In some embodiments, the target paraboloid deformation Ã₄ can be selected with at least an excess magnitude A_{E} over the minimum needed to overcompensate for the substrate deformation, e.g.,

$${\tilde{A}}_{4} {Z}_{4} ( ρ , ϕ ) + h ( r , ϕ ) > {A}_{E} {Z}_{4} ( ρ , ϕ ) .$$

The excess magnitude A_{E} can be empirically selected and can depend on the specific material used for the deformation-compensating film.

Once the target paraboloid deformation Ã₄ has been determined, the thickness of the mask d can be selected using a calibration data that tabulates or otherwise defines a function d=ƒ(Ã₄). In some embodiments, the function ƒ(Ã₄) can be a non-linear function. In some embodiments, the function ƒ(Ã₄) can be a linear function, d=αÃ₄, with a coefficient of proportionality α determined based on mathematical modeling of elastic equations for specific mask material(s), using empirical calibration, or any combination thereof.

In some embodiments, decision-making block 545 can be absent, e.g., in situations where a type (material) of the mask and its thickness is fixed by specifics of the device being manufactured and/or specification of the manufacturing process. In some embodiments, limited operations of the decision-making block 545 can be performed. For example, with the type (material) of the mask fixed by the specification of the technological process, the thickness of the mask can still be selected based on deformation of the substrate measured at block 530.

At block 550, the mask (also serving as SCL) of the selected thickness d (of a fixed thickness) can be deposited on the front side of the substrate. At optional block 555, a shape of the substrate with the deposited mask can be re-measured and the new expansion coefficients {Aⱼ} can be determined. At block 560, method 500 can include determining (e.g., computing) local dose maps for irradiation of the mask. In some embodiments, the dose maps can be computed based on the expansion coefficients A₅, A₆ (to compensate for the saddle deformation) and A₇, A₈ . . . (to compensate for the residual deformation). At block 570, method 500 can continue with irradiating the mask (e.g., according to the computed irradiation doses) with a stress-mitigation beam to reduce the amount of stress in the substrate/films/mask structure and flatten the structure. The stress-mitigation beam can include ions, photons, electrons, and/or any combination thereof. At block 580, method 500 can further include adding one or more features to at least some of the one or more deposited films. For example, operations of block 580 can include etching, using the mask (SCL), one or more channels across at least some of the one or more deposited films, e.g., by forming a photoresist layer on the mask, performing, using the photoresist layer, one or more lithographic operations to create a pattern of openings in the mask, and etching the one or more channels across at least some of the one or more deposited films via the pattern of openings in the mask (SCL). In some embodiments, operations of block 580 can include adding one or more conducting features to the one or more deposited films via the one or more etched channels. In some embodiments, operations of block 580 can include causing a second wafer to adhere to the mask (SCL) and adding the one or more features via a back surface of the substrate. Adding such feature(s) can include thinning the back surface of the substrate to expose some of the one or more deposited films and forming the one or more features in contact with the at least one of the one or more deposited films. Various additional operations can be performed as part of block 580, as prescribed by the manufacturing specification, such as covering the mask (SCL) with DARC/BARC, opening the mask, and/or performing any other suitable operations.

At block 590, operations of method 500 can include removing the mask (or the remnants of the mask remaining after etching).

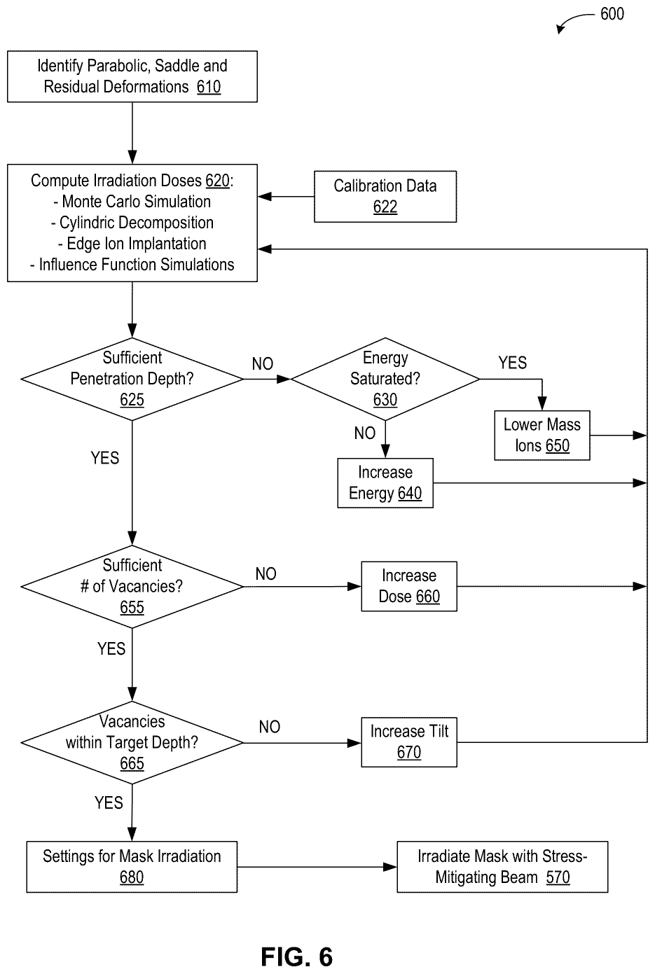

FIG. 6 is a flowchart illustrating an example method 600 of determining front-side irradiation parameters, in accordance with at least one embodiment, in accordance with at least one embodiment. Method 600 can be performed as part of blocks 530-650 of method 500. At block 610, method 600 can include identifying some or all of a parabolic deformation (e.g., Zernike coefficients A₄), saddle deformation (e.g., Zernike coefficients A₅, A₆), and the residual deformation (e.g., Zernike coefficients A₇, A₈ . . . ) of a substrate, e.g., using profilometry measurements.

At block 620, method 600 can continue with computing irradiation doses n(\vec{r}) for the mask deposited on the substrate. Operations of block 620 can include one or more techniques for determining n(\vec{r}). In some embodiments, irradiation doses n(\vec{r}) can be computed using Monte Carlo simulations. In some embodiments, irradiation doses n(\vec{r}) can be computed using cylindrical decomposition of h_{WF}(\vec{r}).

In some embodiments, irradiation doses n(\vec{r}) can be computed (and then applied at block 570) for selected edge regions of the mask. More specifically, operations of block 620 can include identifying principal axes (directions) and a magnitude of a saddle deformation, e.g., σⱼₖ∝cos(2ϕ+α), and further identifying edge regions of the mask as targets for stress-mitigation irradiation to achieve efficient flattening of the substrate. Further (finer) reduction of stresses of the substrate can be achieved by irradiation into a broader area of the mask, e.g., to mitigate a residual substrate deformation remaining after edge irradiation.

In some embodiments, the irradiation doses n(\vec{r}) can be computed using an influence function G(\vec{r}; \vec{r}′), also known as the Green's function, which characterizes a response (e.g., deformation) of the substrate at a point \vec{r} of the substrate as caused by a point-like force applied at a point \vec{r}′ of the substrate. In some embodiments, the influence function G(\vec{r}; \vec{r}′) can be determined from computational simulations or analytical calculations. In some embodiments, the influence function can be determined from one or more experiments, which can include performing ion implantation into a film deposited on a reference substrate. In some embodiments, a combination of multiple techniques of determining the influence function G(\vec{r}; \vec{r}′) can be used.

As a way of example, the Monte Carlo simulations for a structure (e.g., substrate with films and a mask deposited thereon) can be performed for specific materials of the structure (e.g., silicon substrate, stack of ON layers, stack of Si/SiGe layers, carbon mask, and/or the like) and for a specific thickness of the structure. An initial Monte Carlo simulation can be performed for baseline (default) conditions of beam irradiation (e.g., default settings of an ion implantation apparatus or a light-emitting apparatus). The baseline conditions can include a default type of particles (ions, photons, electrons), a default energy of particles, a default dose of particles to be directed to the mask (e.g., a default velocity of scanning and a default scanning pattern), and the like.

In some embodiments, various techniques of irradiation dose computations can use calibration data 622 collected for actual irradiation performed for various types of the irradiation beams, energies of the irradiation beams, types and materials of structures being irradiated, angles of beam incidence on the structures, and/or the like. In some embodiments, calibration data 622 can be statistically preprocessed. For example, various measurements can be collected for multiple substrate/film/mask materials, types of particles, angles of incidence, and/or other parameters. The statistically processed measurements can be stored (e.g., in a memory of a processing device performing computation of the irradiation doses) in the form of probability distributions of various quantities, including but not limited to:
distribution of the density of ion implantation with depth for different ion types, ion energies, angles of incidence;
distribution of the number of vacancies produced at different depths (per unit of length of travel of the ions) for different types of irradiation particles (ions, photons, electrons), particle energies, and angles of incidence;
distribution of stresses created by irradiation beams for different beam intensities and durations; and/or the like.

Performing irradiation dose computations of block 620 can include sampling from the stored distributions and identifying a likelihood that a target stress mitigation will be achieved with the default settings of conditions of beam irradiation of a mask of a given type and thickness. Method 600 can include several verification operations designed to determine whether the target stress can be achieved without detrimentally affecting properties of the substrate/films. For example, at block 625, method 600 can include verifying if the penetration depth of the selected (e.g., default) type of particles is sufficient. For example, the penetration depth is to be at least a certain fraction of the thickness of the mask, e.g., 20%, 30%, 50%, 80%, or more of that thickness. In some embodiments the penetration depth can be up to 100% of the thickness. If the energy is insufficient, method 600 can include checking, at block 630, if the irradiation beam source is capable of outputting particles of a higher energy. If higher energies are available, method 600 can continue with increasing the energy of the particles (block 640) and repeating irradiation dose computations of block 620 for the increased energy. If the maximum energy of the irradiation beam source has already been reached, method 600 can continue with replacing (at block 650) ions with ions of a different type (e.g., if an ion beam is used for irradiation), e.g., replacing Silicon ions with Boron, Carbon, Fluorine, etc., ions, and repeating Monte Carlo simulations for the ions of the new type.

At block 655, method 600 can include verifying whether the number of expected formed vacancies is sufficient. To verify sufficiency, method 600 can assess stress mitigation caused by formed vacancies. In one embodiment, method 600 can begin at some value of stress in the mask, e.g., −3.0 GPa or some other suitable value (negative sign indicating compressive stress) and use beam irradiation to mitigate this stress towards a neutral point, 0.0 GPa at various locales of the mask.

If the number of vacancies is insufficient, method 600 can include increasing a dose of particles (at block 660) and repeating irradiation dose computations of block 620 for the increased dose.

At block 665, method 600 can include verifying that the vacancies are going to be placed within a target depth, e.g., the thickness d of the film or a certain fraction of the film, such as 0.8 d, 0.7 d, 0.5 d, or some other value empirically set to prevent particles from penetrating into the substrate/films and affecting properties of the substrate/films. If the vacancies are to be formed at depths that exceed the target depth, method 600 can include (at block 670) increasing an angle of incidence (e.g., by tilting the irradiation beam) to keep vacancies (as well as substitution impurities) to a shallower region of the mask.

Blocks 620-670 can be repeated multiple times until irradiation dose computations of block 620 are determined to be sufficient that the desired stress mitigation can be achieved, e.g., that the reduction in the tensile stress of the mask is such that the deformation of the substrate is eliminated or at least reduced to an acceptable tolerance. The final settings for mask irradiation (block 680) determined from irradiation dose computations can then be used for irradiation of the mask with the stress-mitigation beam (at block 570).

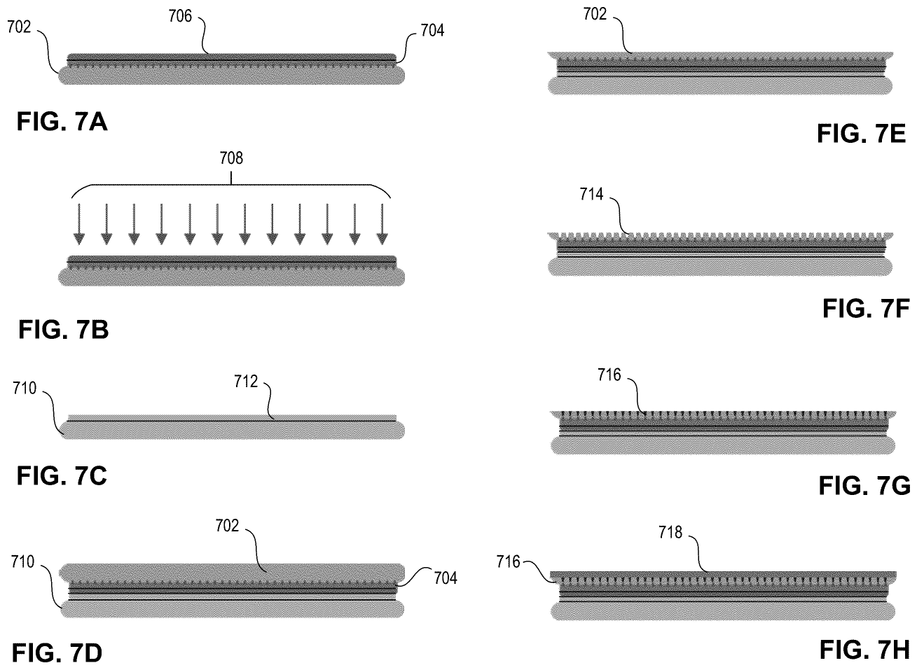

FIGS. 7A-7H illustrates schematically an example process of manufacturing a logic device using a stress-mitigation beam to irradiate a front side-deposited layer, according to at least one embodiment. FIG. 7A depicts a stack of films 704 deposited on a front side of substrate 702. A stress compensation layer 706 is deposited above the stack of films 704. Stress compensation layer 706 can include a dielectric/semiconductor material, a metal material, or combination of one or more dielectric/semiconductor materials and one or more metal materials. Stress compensation layer 706 can be a mask (e.g., a hard mask) deposited for use in an etching operation or some other processing operation. In some embodiments, stress compensation layer 706 can be a film deposited for the purpose of stress mitigation.

As illustrated in FIG. 7B, stress compensation layer 706 can be subjected to a localized stress modification process by exposing stress compensation layer 706 to irradiation 708, e.g., as disclosed above in conjunction with FIGS. 1-6.

FIG. 7C depicts preparation of a substrate carrier 710, e.g., a silicon substrate, a class glass, a plastic waver, or some other type of substrate, having an adhesive layer 712 deposited thereon.

As illustrated with FIG. 7D, the substrate carrier 710 can be turned upside down and attached, using the adhesive layer 712, to stress compensation layer 706 supported by substrate 702.

As illustrated with FIG. 7E, substrate 702 can undergo a partial removal operation (backside thinning), including but not limited to coarse grinding, fine grinding, CMP, wet etching, dry etching, and/or a similar process.

As illustrated with FIG. 7F, the remaining part of substrate 702 can undergo a lithographic patterning, e.g., to form openings for conductive channels.

As illustrated with FIG. 7F, patterning 714 can be filled with one or more conducting materials 716 and can further undergo one or more polishing operations.

As illustrated with FIG. 7H, one or more additional layers 718 of conducting or insulating materials can be deposited, e.g., using metal interconnect dual damascene processing operations, or other suitable operations.

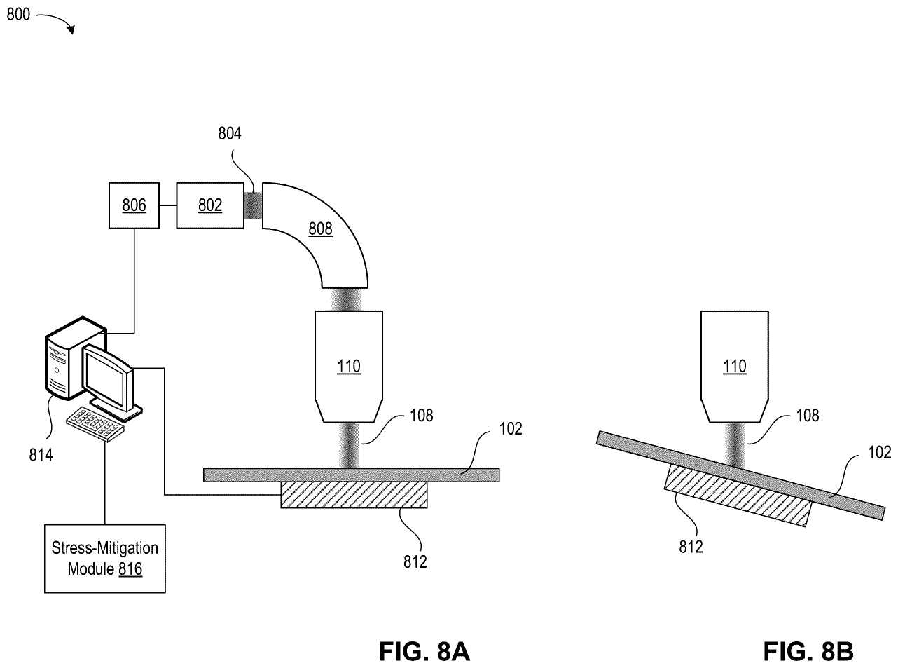

FIG. 8A illustrates schematically an irradiation system 800 capable of performing irradiation of stress compensation layers, according to at least one embodiment. Irradiation system 800 can include collimating and focusing column 110 of FIG. 1. Irradiation system 800 can further include a beam source 802 for producing a source beam 804. Beam source 802 can include a chamber for generating ions (e.g., a plasma chamber), a light source for generating photons (e.g., a laser, laser diode, lamp, etc.), a heated filament for producing electrons, and/or any other source for the particles of a type deployed in specific stress-mitigation techniques of the instant disclosure. Beam source 802 can be powered by a power element 806 and can include an extraction electrode assembly (not shown). Irradiation system 800 can include a mass spectrometer 808 (e.g., in the instances where beam source 802 produces charged particles, such as electrons or ions) and a collimating and focusing column 110. Collimating and focusing column 110 can direct stress-mitigation beam 108 to substrate 102. Substrate 102 can be supported by a support stage 812. In some embodiments, support stage 812 and substrate 102 can remain stationary during irradiation of substrate 102 by stress-mitigation beam 108 while components of irradiation system 800 can be repositioned relative to substrate 102. In some embodiments, irradiation system 800 can be stationary while support stage 812 can reposition substrate 102. In some embodiments, stress-mitigation beam 108 can have intensity (e.g., light intensity) that is modulated by changing intensity of beam source 802 and/or placing a partially absorbing or partially reflecting material at some location between beam source 802 and substrate 102. This enables delivery of local irradiation doses n(x,y) to various locations of substrate 102. Scanning with stress-mitigation beam 108 can occur along multiple directions, e.g., along x-axis and along y-axis according to any suitable predetermined pattern, e.g., back-and forth along x-axis, in a spiral pattern, and so on. In various embodiments, stress-mitigation beam 108 can be scanned with a frequency of several Hz, tens of Hz, hundreds of Hz, thousands of Hz, or more.

Operations of irradiation system 800 can be controlled by a controller 814, which can include any suitable computing device, microcontroller, or any other processing device having a processor, e.g., a central processing unit (CPU), a field-programmable gate array (FPGA), an application-specific integrated circuit (ASIC), and/or the like, and a memory device, e.g., a random-access memory (RAM), read-only memory (ROM), flash memory, and/or the like or any combination thereof. Controller 814 can control operations of power element 806, support stage 812, and/or various other components and modules of irradiation system 800. Controller 814 can include a stress-mitigation module 816 capable of performing simulations that determine a target intensity of stress-mitigation beam 108 to be used to mitigate various wafer deformations. In some embodiments, as illustrated in FIG. 8B, support stage 812 can impart a tilt, e.g., in one or two spatial directions to substrate 102 to change an angle of incidence of stress-mitigation beam 108 relative to substrate 102. In some embodiments, instead of tilting substrate 102, controller 814 can cause a tilt of stress-mitigation beam 108 relative to substrate 102.

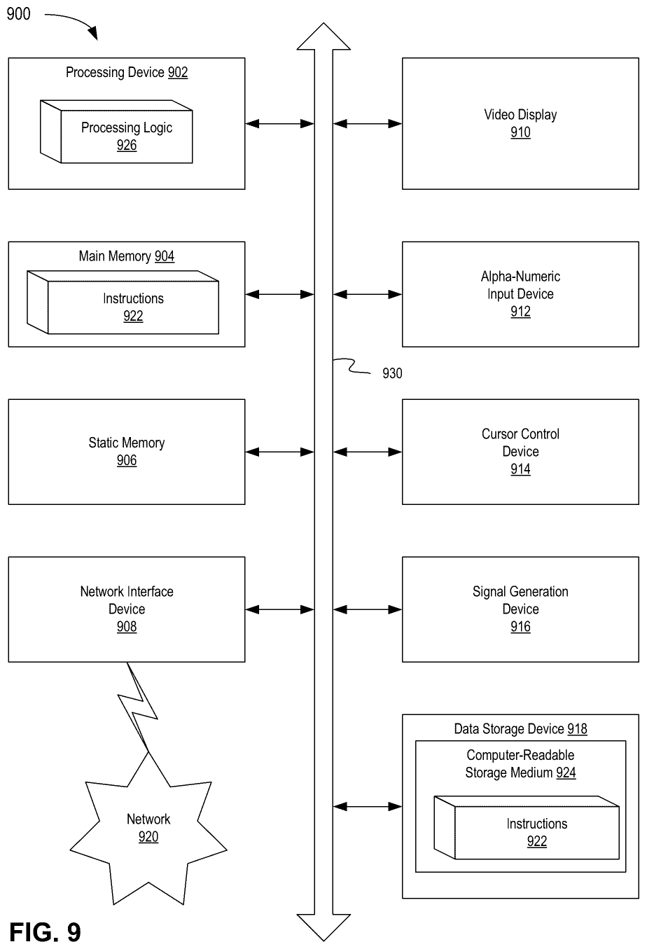

FIG. 9 depicts a block diagram of an example computer system 900 capable of supporting operations of the present disclosure, according to at least one embodiment. In various illustrative examples, example computer system 900 may be or include controller 814 of FIG. 8. Example computer system 900 may be connected to other computer systems in a LAN, an intranet, an extranet, and/or the Internet. Computer system 900 may operate in the capacity of a server in a client-server network environment. Computer system 900 may be a personal computer (PC), a set-top box (STB), a server, a network router, switch or bridge, or any device capable of executing a set of instructions (sequential or otherwise) that specify actions to be taken by that device. Further, while only a single example computer system is illustrated, the term “computer” shall also be taken to include any collection of computers that individually or jointly execute a set (or multiple sets) of instructions to perform any one or more of the methods discussed herein.

Example computer system 900 may include a processing device 902 (also referred to as a processor or CPU), a main memory 904 (e.g., read-only memory (ROM), flash memory, dynamic random access memory (DRAM) such as synchronous DRAM (SDRAM), etc.), a static memory 906 (e.g., flash memory, static random access memory (SRAM), etc.), and a secondary memory (e.g., a data storage device 918), which may communicate with each other via a bus 930.

Processing device 902 represents one or more general-purpose processing devices such as a microprocessor, central processing unit, or the like. More particularly, processing device 902 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 902 may also be one or more special-purpose processing devices such as an application specific integrated circuit (ASIC), a field programmable gate array (FPGA), a digital signal processor (DSP), network processor, or the like. In accordance with one or more aspects of the present disclosure, processing device 902 may include a processing logic 926 configured to execute instructions (e.g., instructions 922) implementing example method 500 of mitigation of wafer stress and deformation using front-side irradiation and/or method 600 of determining front-side irradiation parameters, in accordance with at least one embodiment.

Example computer system 900 may further comprise a network interface device 908, which may be communicatively coupled to a network 920. Example computer system 900 may further comprise a video display 910 (e.g., a liquid crystal display (LCD), a touch screen, or a cathode ray tube (CRT)), an alphanumeric input device 912 (e.g., a keyboard), a cursor control device 914 (e.g., a mouse), and an acoustic signal generation device 916 (e.g., a speaker).

Data storage device 918 may include a computer-readable storage medium (or, more specifically, a non-transitory computer-readable storage medium) 924 on which is stored one or more sets of executable instructions 922. In accordance with one or more aspects of the present disclosure, executable instructions 922 may comprise executable instructions implementing example method 500 of mitigation of wafer stress and deformation using front-side irradiation and/or method 600 of determining front-side irradiation parameters, in accordance with at least one embodiment.

Executable instructions 922 may also reside, completely or at least partially, within main memory 904 and/or within processing device 902 during execution thereof by example computer system 900, main memory 904 and processing device 902 also constituting computer-readable storage media. Executable instructions 922 may further be transmitted or received over a network via network interface device 908.

While the computer-readable storage medium 924 is shown in FIG. 9 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other implementation examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method of manufacturing a semiconductor device, the method comprising:
depositing one or more films on a front surface of a substrate;
forming a stress-compensation layer (SCL) on the one or more deposited films, the SCL causing stress in the substrate to be changed;
subjecting the SCL to a stress-mitigation beam to reduce deformation of the substrate; and
adding one or more features to at least one of the one or more deposited films.

2. The method of claim 1, wherein the stress-mitigation beam comprises at least one of: a beam of ions, a beam of photons, or a beam of electrons.

3. The method of claim 1, wherein adding one or more features comprises:
etching, using the SCL, one or more channels across at least some of the one or more deposited films.

4. The method of claim 3, wherein etching the one or more channels comprises:
forming a photoresist layer on the SCL;
performing, using the photoresist layer, one or more lithographic operations to create a pattern of openings in the SCL; and
etching the one or more channels across at least some of the one or more deposited films via the pattern of openings in the SCL.

5. The method of claim 4, further comprising:
adding one or more conducting features to the one or more deposited films via the one or more etched channels.

6. The method of claim 1, further comprising:
removing the SCL after adding the one or more features.

7. The method of claim 1, wherein adding the one or more features to the at least one of the one or more deposited films comprises:
causing a second wafer to adhere to the SCL; and
adding the one or more features via a back surface of the substrate.

8. The method of claim 7, wherein adding the one or more features via the back surface of the substrate comprises:
thinning the back surface of the substrate to expose the at least one of the one or more deposited films; and
form the one or more features in contact with the at least one of the one or more deposited films.

9. The method of claim 1, further comprising:
obtaining optical inspection data characterizing a profile of the deformation of the substrate; and
determining settings of the stress-mitigation beam using the optical inspection data.

10. The method of claim 9, wherein the settings for the stress-mitigation beam comprise one or more of:
a type of particles of the stress-mitigation beam,
an energy of the particles of the stress-mitigation beam, or
an angle of incidence of the particles of the stress-mitigation beam.

11. A system comprising:
a memory; and
a processing device communicatively coupled to the memory, wherein the processing device is to cause performance of operations comprising:
depositing one or more films on a front surface of a substrate;
forming a stress-compensation layer (SCL) on the one or more deposited films, the SCL causing stress in the substrate to be changed;
subjecting the SCL to a stress-mitigation beam to reduce deformation of the substrate; and
adding one or more features to at least one of the one or more deposited films.

12. The system of claim 11, wherein the stress-mitigation beam comprises at least one of: a beam of ions, a beam of photons, or a beam of electrons.

13. The system of claim 11, wherein adding one or more features comprises:
etching, using the SCL, one or more channels across at least some of the one or more deposited films.

14. A semiconductor manufacturing system comprising:
one or more processing chambers to:
deposit one or more films on a front surface of a substrate;
form a stress-compensation layer (SCL) on the one or more deposited films, the SCL causing stress in the substrate to be changed;
subject the SCL to a stress-mitigation beam to reduce deformation of the substrate; and
add one or more features to at least one of the one or more deposited films.

15. The semiconductor manufacturing system of claim 14, wherein to add one or more features, the one or more processing chambers are to:
etch, using the SCL, one or more channels across at least some of the one or more deposited films.

16. The semiconductor manufacturing system of claim 15, wherein to etch the one or more channels, the one or more processing chambers are to:
form a photoresist layer on the SCL;
perform, using the photoresist layer, one or more lithographic operations to create a pattern of openings in the SCL; and
etch the one or more channels across at least some of the one or more deposited films via the pattern of openings in the SCL.

17. The semiconductor manufacturing system of claim 16, wherein the one or more processing chambers are further to:
add one or more conducting features to the one or more deposited films via the one or more etched channels.

18. The semiconductor manufacturing system of claim 14, wherein the one or more processing chambers are further to:
remove the SCL after adding the one or more features.

19. The semiconductor manufacturing system of claim 14, wherein to add the one or more features to the at least one of the one or more deposited films, the one or more processing chambers are to:
cause a second wafer to adhere to the SCL; and
add the one or more features via a back surface of the substrate.

20. The semiconductor manufacturing system of claim 19, wherein to add the one or more features to the at least one of the one or more deposited films, the one or more processing chambers are further to:
thin the back surface of the substrate to expose the at least one of the one or more deposited films; and
form the one or more features in contact with the at least one of the one or more deposited films.
